(19) United States
(12) Patent Application Publication
(10) Pub. No.: US 2026/0068366 A1
(43) Pub. Date: Mar. 5, 2026

(54) WAVELENGTH-CONVERTED LIGHT-EMITTING DIODES WITH LATERAL CONTACT GEOMETRY

(71) Applicant: Lumileds LLC, San Jose, CA (US)

(72) Inventors: Jeff DiMaria, Scotts Valley, CA (US); Yu-Chen Shen, Sunnyvale, CA (US); Antonio Lopez-Julia, Vaals (NL); Oleg Borisovich Shchekin, San Francisco, CA (US); Joseph Flemish, San Jose, CA (US)

(73) Assignee: Lumileds LLC, San Jose, CA (US)

(21) Appl. No.: 18/823,461

(22) Filed: Sep. 3, 2024

(51) Int. Cl. H01L 33/38; H01L 33/06; H01L 33/24; H01L 33/44; H01L 33/46; H01L 33/50

(52) U.S. Cl. CPC H10H 20/8314; H10H 20/812; H10H 20/821; H10H 20/84; H10H 20/841; H10H 20/8514

(57) ABSTRACT

An LED includes first/second doped layers with active region(s) therebetween emitting a first wavelength. A wavelength converter on a first LED surface absorbs the first wavelength and emits a second, longer wavelength. A second LED surface is against a substrate surface. A first electrical contact on the first LED surface extends along LED sidewalls, separated from the active region(s) and second doped layer by an insulating layer, connecting the first doped layer to a first contact pad. In some instances, contact pads are on the substrate surface; a second electrical contact extends onto LED sidewalls, connecting the second doped layer to a second contact pad. In some other instances contact pads are on laterally-extending portions of the second doped layer. The insulating layer separates the first contact pad from the second doped layer; a second contact pad is in direct electrical contact with the second doped layer.

### FIELD OF THE INVENTION

The field of the present invention relates to light-emitting diodes (LEDs). Wavelength-converted LEDs are described herein having a lateral contact geometry.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

In some instances, the light directly emitted by the active region of an LED can comprise its entire output; such an LED can be referred to as a direct emitter, or a direct-emitting LED. The LEDs of the present disclosure are combined with one or more wavelength-converting materials (also referred to herein as “phosphors”) that absorb light emitted by the LED active region and in response emit light of a longer wavelength. Hereinafter the term LED shall denote such wavelength-converted LEDs, unless explicitly stated otherwise. For wavelength-converted LEDs (sometimes referred to as phosphor-converted LEDs), the fraction of the light emitted by the LED active region that is absorbed by the phosphors depends on the amount of phosphor material in the optical path of the light emitted by the LED active region, for example on the concentration of phosphor material in a phosphor layer disposed on or around the LED and the thickness of the layer. Wavelength-converted LEDs can be designed so that all of the light emitted by the LED active region is absorbed by one or more phosphors, in which case the overall output of the wavelength-converted LED is entirely from the one or more phosphors. In such cases one or more phosphors can be selected, for example, to emit light in one or more corresponding narrow spectral regions that are not efficiently generated directly by the LED active region, or to emit white light having a desired color temperature or desired color-rendering properties. Alternatively, wavelength-converted LEDs can be designed so that only a portion of the light emitted by the LED active region is absorbed by the phosphor(s), in which case the emission from the wavelength-converted LED is a mixture of light emitted by the LED active region and light emitted by the phosphor(s). By suitable choice of LED, phosphor(s), and phosphor composition, such a wavelength-converted LED can be designed to emit, for example, white light having a desired color temperature or desired color-rendering properties.

Multiple LEDs can be formed together on a single substrate to form an array.

Such arrays can be employed to form active illuminated displays, such as those employed in, e.g., smartphones and smart watches, computer or video displays, augmented-or virtual-reality displays (i.e., visualization systems), or signage, or to form adaptive illumination sources, such as those employed in, e.g., automotive headlights, street lighting, camera flash sources, or flashlights (i.e., torches). An array having one or several or many individual devices per millimeter (e.g., device pitch or spacing of about a millimeter, a few hundred microns, less than 50 or 100 microns, or even smaller, and/or separation between adjacent devices less than 100 microns or only a few tens of microns or even less) typically is referred to as a miniLED array or a microLED array (alternatively, a μLED array).

### SUMMARY

A wavelength-converted light-emitting device includes a semiconductor light-emitting diode (LED), a wavelength converter, first and second electrical contact pads, first and second electrical connections, and a first insulating layer. The LED includes first and second doped layers with one or more active regions between them. The active region(s) emit first output light in a first output wavelength range. The first doped layer is between a first LED surface and the active region(s); the second doped layer is between a second LED surface and the active region(s). LED sidewalls extend from the first LED surface toward the second LED surface. The LED is positioned with its second surface on a substrate surface. The wavelength converter is positioned on at least the first LED surface, and absorbs at least a portion of the first output light that enters the wavelength converter and emits second output light in a second output wavelength range that is longer than the first output wavelength range.

The first and second electrical contact pads are positioned on the LED, or on the substrate surface adjacent the LED, and are electrically isolated from each other. A first electrical contact, on at least a portion of the first LED surface, is in direct electrical contact with the first doped layer of the LED and extends over a portion of the LED sidewalls to form the first electrical connection, between the first contact pad and the first doped layer. The second electrical connection is between the second contact pad and the second doped layer. A first electrically insulating layer, on a portion of the LED sidewalls, separates the first electrical contact from the one or more active regions and from the second doped layer.

In some examples the LED sidewalls connect the first and second LED surfaces, and the first and second contact pads are positioned on the substrate surface adjacent the LED. A second electrical contact is in direct electrical contact with the second doped layer of the LED and forms the second electrical connection.

In some other examples the LED includes lateral portions of the second doped layer that extend laterally from the LED sidewalls along the substrate surface, and the first and second contact pads are positioned on the lateral portions of the second doped layer. A portion of the first electrically insulating layer extends onto the lateral portion of the second doped layer and separates the first contact pad from the second doped layer. The second contact pad is in direct electrical contact with the second doped layer to form the second electrical connection.

Objects and advantages pertaining to wavelength-converted LEDs may become apparent upon referring to the example embodiments illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a schematic cross-sectional view of an example wavelength-converted LED.

FIGS. 2A and 2B show, respectively, cross-sectional and top schematic views of an example array of LEDs.

FIG. 3 is a top schematic view of an example LED array and an enlarged section of 3×3 LEDs of the array.

FIGS. 4 through 16 are schematic cross-sectional views of various examples of a wavelength-converted LED.

The embodiments depicted are shown only schematically; all features may not be shown in full detail or in proper proportion; for clarity certain features or structures may be exaggerated or diminished relative to others or omitted entirely (e.g., exaggerated thicknesses of optical coatings or transparent conductive layers); the drawings should not be regarded as being to scale unless explicitly indicated as being to scale. In the drawings some schematic illustrations of example structures of various devices and assemblies described herein may be shown with precise right angles and straight lines, but it is to be understood that such schematic illustrations may not reflect real-life process limitations or defects. Such process limitations or defects can cause the features to look not so “ideal” when any of the structures described herein are examined using, e.g., scanning electron microscopy (SEM) images or transmission electron microscope (TEM) images. In such images of real structures, possible processing limitations or defects might be visible, e.g., not-perfectly straight edges of materials, tapered vias or other openings, inadvertent rounding of corners or variations in thicknesses of different material layers. There may be other limitations or defects not listed here that can occur within the field of device fabrication. The embodiments shown are only examples and should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the inventive subject matter. The detailed description illustrates by way of example, not by way of limitation, the principles of the inventive subject matter.

For purposes of the present disclosure and appended claims, any arrangement of a layer, surface, substrate, diode structure, wavelength converter, or other structure “on,” “over,” or “against” another such structure shall encompass arrangements with direct contact between the two structures as well as arrangements including some intervening structure between them. Conversely, any arrangement of a layer, surface, substrate, diode structure, or other structure “directly on,” “directly over,” or “directly against” another such structure shall encompass only arrangements with direct contact between the two structures. For purposes of the present disclosure and appended claims, a layer, coating, structure, or material described as “transparent” or “substantially transparent” shall exhibit, over one or more pertinent wavelength ranges, a level of optical transmission that is sufficiently high, or a level of optical loss (due to absorption, scattering, reflection, or other loss mechanism) that is sufficiently low, that the light-emitting device can function within operationally acceptable parameters (e.g., output power or luminance, conversion or extraction efficiency, or other figures-of-merit including any described below). Similarly, a layer, coating, structure, or material described as “reflective” shall exhibit reflectivity that is sufficiently high, over one or more pertinent wavelength ranges, that the light-emitting device can function within operationally acceptable parameters such as those listed above or described below.

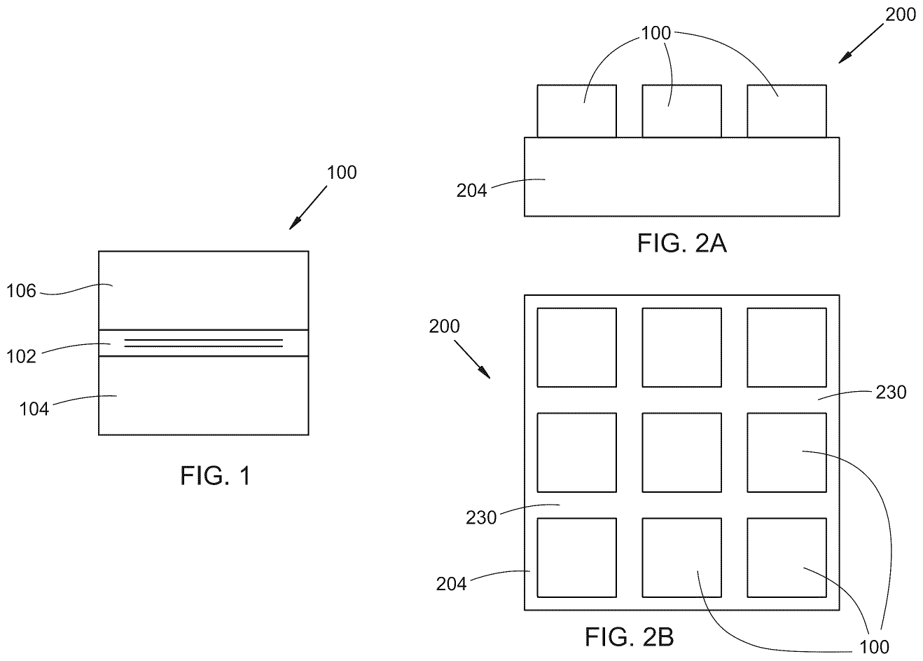

FIG. 1 shows an example of an individual wavelength-converted LED 100 comprising a semiconductor diode structure 102 (i.e., LED 102) disposed on a substrate 104 and a wavelength converter 106 (e.g., a phosphor layer) disposed on the LED 102. In the present disclosure “LED 100” shall denote a wavelength-converted LED generally arranged as in FIG. 1 (including both the LED 102 and the wavelength converter 106), while “semiconductor LED 102” or simply “LED 102” shall denote only the semiconductor LED (without the wavelength converter 106). The semiconductor LED 102 typically comprises an active region disposed between n-type and p-type doped semiconductor layers; examples of an active region can include a junction between the n- and p-type layers, or one or more active layers between the n- and p-type layers (e.g., quantum well, multi-quantum well, quantum dots, and so forth). Application of a suitable forward bias across the LED 102 results in emission of first output light from the active region in a first output wavelength range. The wavelength of the emitted first output light is determined by the composition and structure of the active region and composition of the doped layers.

The LED 102 can be, for example, a III-Nitride LED that emits red, green, blue, violet, or ultraviolet light from its active region. Diode structures formed from any other suitable material system and that emit any other suitable wavelength of light can be employed. Other suitable material systems can include, e.g., III-Phosphide materials, III-Arsenide materials, other binary, ternary, or quaternary mixtures, compounds, or alloys of gallium, aluminum, indium, nitrogen, phosphorus, arsenic, or other III-V materials, or II-VI materials, or Group IV materials.

Any suitable wavelength-converting materials may be used for or incorporated into the wavelength converter 106, depending on the desired optical output from the wavelength-converted LED 100. Some examples can include, e.g., suitably doped ceramics, phosphor particles embedded in a suitable matrix material (e.g., a silicone or other polymer), or quantum dots. The wavelength converter 106 absorbs at least a portion of the first output light that enters the wavelength converter and emits second output light in a second output wavelength range that is longer than the first output wavelength range FIGS. 2A and 2B show, respectively, cross-sectional and top views of an array 200 of LEDs 100 disposed on a substrate 204. Such an array can include any suitable number of LEDs arranged in any suitable manner. In the illustrated example the array is depicted as being formed monolithically on a shared substrate; alternatively, an array of LEDs can be formed from separate individual LEDs (e.g., singulated devices that are assembled onto an array substrate). In an array of wavelength-converted LEDS, individual wavelength-converting pixels 106 can be positioned on each semiconductor diode pixel 102; alternatively, a continuous layer of wavelength-converting material can be disposed across multiple semiconductor LEDs 102. LEDs 100 in the array 200 may be spaced apart from each other by streets, lanes, or trenches 230. Arrays of the present disclosure can include light barriers (e.g., reflective, scattering, and/or absorbing) in the lanes 230 between adjacent LEDs 102, wavelength converters 106, or both; those light barriers can in some instances include one or more electrodes, metal layers, dielectric layers, multilayer coatings, and so forth on sidewalls of the LEDs. Some examples of those are described below.

Individual LEDs 100 of an array 200 can optionally incorporate or be arranged in combination with a lens or other optical element located adjacent to or disposed on the LED or wavelength converter. Such an optical element (not shown in the drawings) can be referred to as a “primary optical element”. Instead or in addition, an LED array 200 (for example, mounted on an electronics board) can be arranged in combination with secondary optical elements such as waveguides, lenses, or both (not shown in the drawings) for use in an intended application. Other primary or secondary optical elements of any suitable type or arrangement can be included for each pixel or for an array of pixels, as needed or desired, depending on the desired application (e.g., display, illumination source, and so forth).

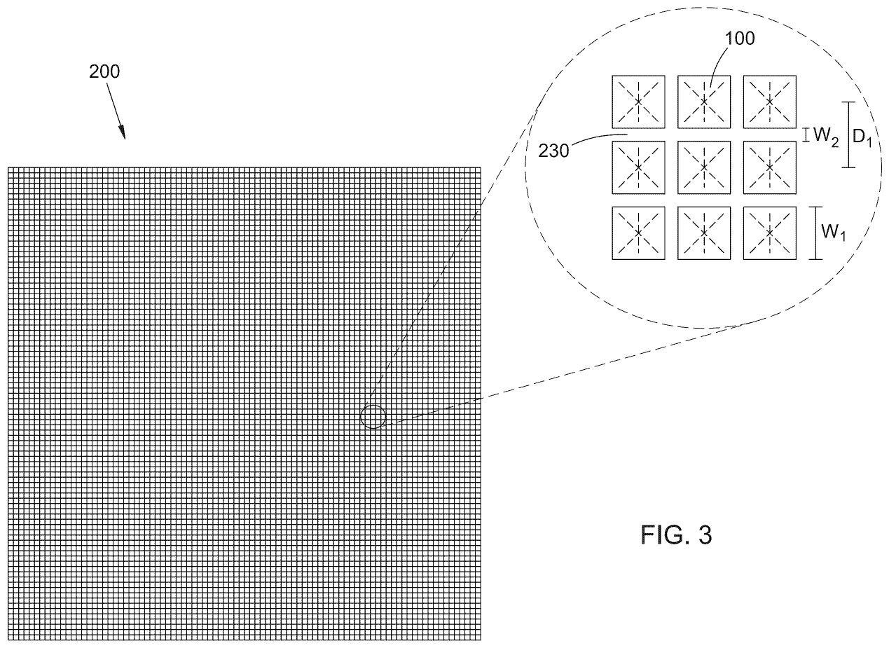

Although FIGS. 2A and 2B show a 3×3 array of nine LEDs, LED arrays can include for example on the order of 10¹, 10², 10³, 10⁴, or more LEDs, e.g., as illustrated schematically in FIG. 3. In some examples individual LEDs 100 (i.e., pixels) may have widths w₁ (e.g., side lengths) in the plane of the array 200, for example, less than or equal to 1 millimeter (mm), less than or equal to 500 microns, less than or equal to 100 microns, less than or equal to 50 microns, or even smaller. LEDs 100 in the array 200 may be spaced apart from each other by the streets, lanes, or trenches 230 having a width w₂ in the plane of the array 200 of, for example, hundreds of microns, less than or equal to 100 microns, less than or equal to 50 microns, less than or equal to 20 microns, less than or equal to 10 microns, or less than or equal to 5 microns. The pixel pitch or spacing D₁ is the sum of w₁ and w₂. LEDs having dimensions w₁ in the plane of the array (e.g., side lengths) of less than or equal to about 200 microns are typically referred to as microLEDs or μLEDs, and an array of such microLEDs may be referred to as a microLED array. LEDs having dimensions w₁ in the plane of the array (e.g., side lengths) of between about 0.10 millimeters and about 1.0 millimeters are typically referred to as miniLEDs, and an array of such miniLEDs may be referred to as a miniLED array. In some examples larger LEDs can be employed. Although the illustrated examples show rectangular pixels arranged in a symmetric, regular array, the pixels and the array may have any suitable shape or arrangement, whether symmetric or asymmetric, regular or irregular. Multiple separate arrays of LEDs can be combined in any suitable arrangement in any applicable format to form a larger combined array or display.

One source of inefficiency of a wavelength-converted LED is that a fraction of the first output light that does not exit the LED 102 through a first LED surface and enter the wavelength converter 106. Some of that first output light might exit the LED 102, e.g., through LED sidewalls or a second LED surface opposite the first LED surface. Another source of inefficiency is propagation of second output light emitted by the wavelength converter 106 toward the LED 102, instead of exiting the wavelength-converting 106 structure to propagate away from the wavelength-converted LED 100.

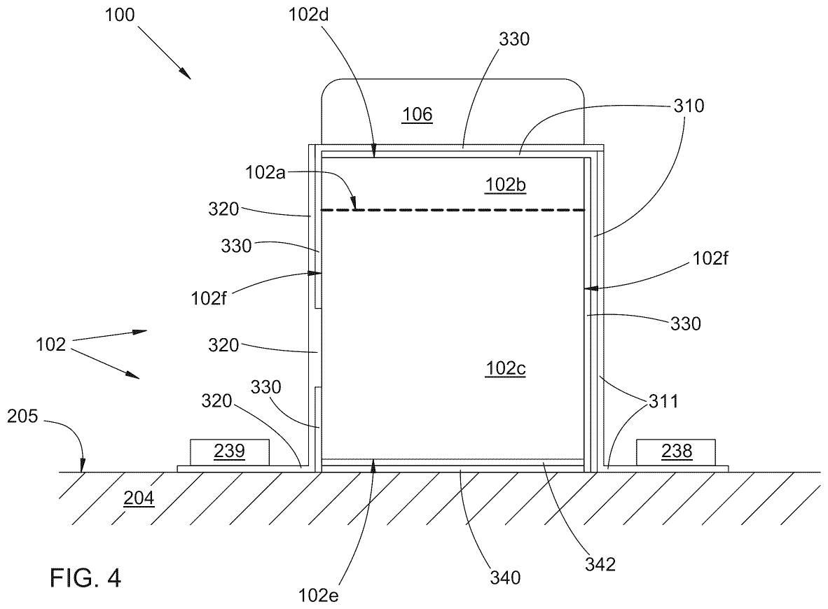

Schematic cross-sectional views of various examples of wavelength-converted LEDs 100 are shown in FIGS. 4 through 16 in which various adaptations are implemented for increasing, e.g., the fraction of the first output light that exits the LED 102 and enters the wavelength converter 106, or the fraction of the second output light that exits the wavelength converter 106 and propagates away from the wavelength-converted LED 100.

Each inventive wavelength-converted LED 100 of the present disclosure includes a semiconductor LED 102, a wavelength converter 106, electrical contact pads 238 and 239, first and second electrical connections, and an insulating layer 330.

The LED 102 has opposite first and second LED surfaces 102d and 102e, respectively, and LED sidewalls 102f extending from the first LED surface 102d toward the second LED surface 102e. The LED 102 is positioned on a surface 205 of a substrate 204 with the second LED surface 102e on the substrate surface 205. The LED 102 includes one or more light-emitting active regions 102a, a first doped semiconductor layer 102b between the first LED surface 102d and the active region(s), and a second doped semiconductor layer 102c between second LED surface 102e and the active region(s) 102a. In many examples the doped layer 102b can be a p-doped layer and the doped layer 102c can be an n-doped layer. The LED 102 can include one or more doped or undoped III-V, II-VI, or Group IV semiconductor materials, or mixtures, alloys, or compounds thereof. The one or more light-emitting active regions 102a are arranged between the doped layers 102b/102c in any suitable way to emit first output light in a first output wavelength range, e.g., including one or more quantum wells or multi-quantum wells, or quantum dots of any suitable size, composition, or structure. The first output wavelength range can include UV light or visible light.

The substrate 204 can optionally include electrical traces or interconnects, or CMOS or other circuitry for connecting to the contact pads 238/239 and providing drive current to the LED 102, and can be formed from any suitable materials. The wavelength-converted LED 100 can be a single device (e.g., as in FIG. 1), or can be one device among many similarly arranged wavelength-converted LEDs 100 in an array 200 (e.g., as in FIGS. 2A, 2B, or 3). In some examples individual LEDs 102 (pixels) in an array 200 of multiple LEDs can be individually addressable (i.e., selectively operable); in some examples the LEDs 102 can be addressable as part of a group or subset of the pixels in the array; in some examples the LEDs are not addressable.

The wavelength converter 106 is positioned on at least the first LED surface 102d, and absorbs at least a portion of the first output light that enters the wavelength converter 106 and emits second output light in a second output wavelength range that is longer than the first output wavelength range. Any one or more suitable materials can be employed in the wavelength converter 106, such as phosphor particles of any suitable size or composition, or quantum dots of any suitable size, composition, or structure. Phosphor particles or quantum dots typically are dispersed, embedded, or coated in a suitable transparent medium (e.g., silicones, metal oxides/nitrides, or semiconductor oxides/nitrides). A wavelength converter 106 with quantum dots can be advantageously employed, e.g., in LED arrays with spacing of less than 10 microns or device separation less than a few microns or sub-micron. In some examples the first output wavelength range includes one or more UV or visible wavelengths, the second output wavelength range includes one or more visible wavelengths, and the wavelength converter 106 is arranged to absorb substantially all of the entering first output light, so that overall output of the wavelength-converted light-emitting device 100 includes light in only the second wavelength range. In some other examples both the first and second output wavelength ranges include visible wavelengths, and the wavelength converter 106 is arranged to absorb only a portion of the entering first output light, so that overall output of the wavelength-converted light-emitting device 100 includes light in both the first and second wavelength ranges. In some examples the overall output of the wavelength-converted LED 100 can be white light having a selected color temperature or having specified color rendering properties.

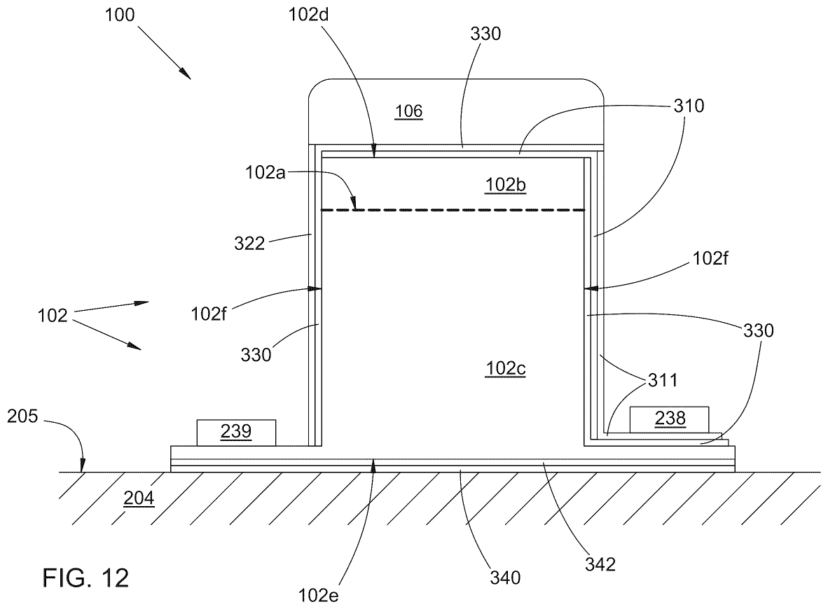

LEDs 100 of the present disclosure are arranged with a lateral contact geometry (also referred to as a lateral die arrangement), as illustrated schematically in the example cross-sectional views of FIGS. 4 through 16. In some examples (e.g., as in FIGS. 12-16) the electrical contact pads 238/239 can be positioned on the LED 102; in some other examples (e.g., as in FIGS. 4-11) the electrical contact pads 238/239 can be positioned on the substrate surface 204 adjacent the LED 102. Wherever they are positioned, the contact pads 238 and 239 are electrically isolated from each other. A first electrical connection is formed between the first doped layer 102b and the first contact pad 238 by a first electrical contact 310 on at least a portion of the first LED surface 102d, where the first electrical contact 310 is in direct electrical contact with the first doped layer 102b. The first electrical contact 310 extends over a portion of the LED sidewalls 102f to form the first electrical connection, between the first contact pad 238 and the first doped layer 102b. The first electrically insulating layer 330, on a portion of the LED sidewalls 102f, separates the first electrical contact 310 from the active region(s) 102a and from the second doped layer 102c, and can comprise any suitable dielectric material (e.g., a metal or semiconductor oxide or nitride). A second electrical connection (further described below) connects the second contact pad 239 and the second doped layer 102c.

In some examples a reflective layer 340 can be positioned between the substrate surface 204 and the doped layer 102c; the layer 340 is reflective over the first output wavelength range, and can be of any suitable type or arrangement, e.g., a metallic reflector, or a dielectric multilayer reflector (e.g., a distributed Bragg reflector). If a metal reflector 340 is employed, it should not create unwanted electrical contact between the contact pads 238/239. The reflective layer 340 redirects first output light incident on the LED surface 102e to propagate toward the LED surface 102d and the wavelength converter 106, increasing efficiency of first output light exiting the LED 102 and entering the wavelength converter 106. In some examples a roughened, patterned, scattering, diffusive, or diffractive surface 342, of any suitable type or arrangement, can be positioned between the reflective layer 340 and the doped layer 102c, further increasing the efficiency of first output light exiting the LED 102.

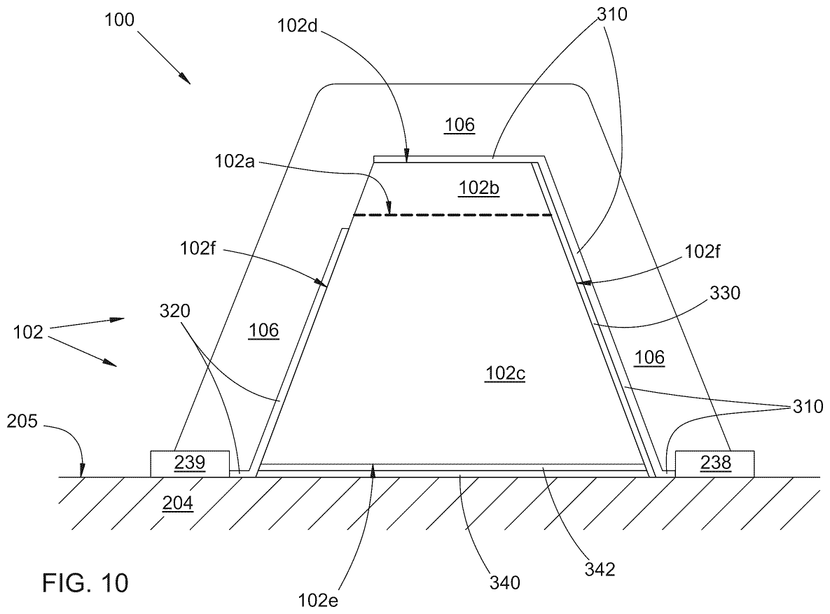

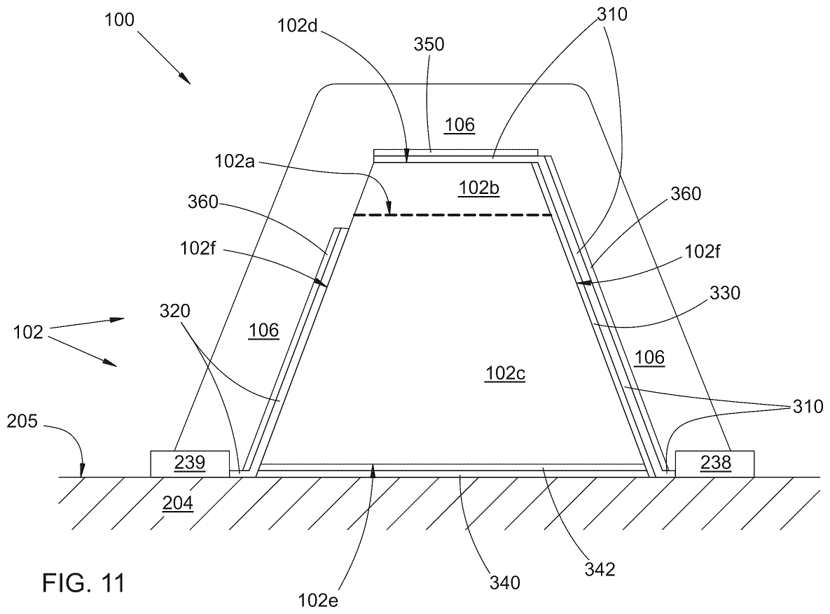

In some examples (e.g., as in FIGS. 4-11), the LED sidewalls 102f connect the first and second LED surfaces 102d/102e, and the contact pads 238/239 are positioned the substrate surface 204 adjacent the LED 102. In such examples a second electrical contact 320 is in direct electrical contact with the doped layer 102c, is electrically isolated from the active region(s) 102a and the doped layer 102b, and connects the contact pad 239 to the doped layer 102c. In some examples having the contact pads 238/239 on the substrate surface 204, the LED sidewalls 102f are perpendicular to the substrate surface 204 (e.g., as in FIGS. 4-9). In some other examples having the contact pads 238/239 on the substrate surface 204, the LED sidewalls 102f form an acute angle with the substrate surface 204 (e.g., as in FIGS. 10 and 11), so that a vertical cross-section of the LED 102 is trapezoidal with the LED surface 102e (on the substrate surface 204) being wider than the LED surface 102d (against the wavelength converter 106). In some instances, the acute angle can be less than 70°. The acute angle of the sidewalls 102f can increase the fraction of the first output light that exits the LED 102 through the sidewalls 102f; in such examples the electrical contacts 310/320 are transparent over the first output wavelength range and the wavelength converter 106 extends onto the sidewalls 102f (e.g., as in FIGS. 10 and 11).

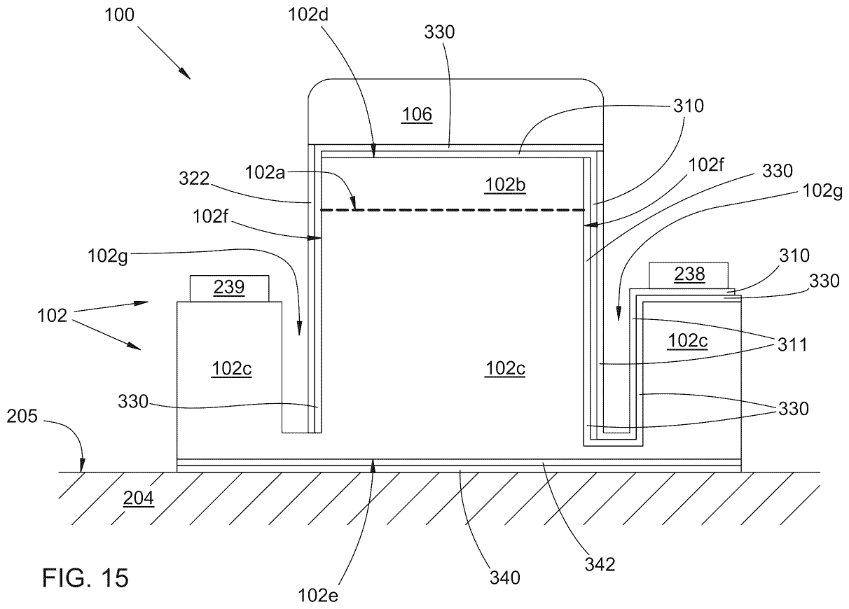

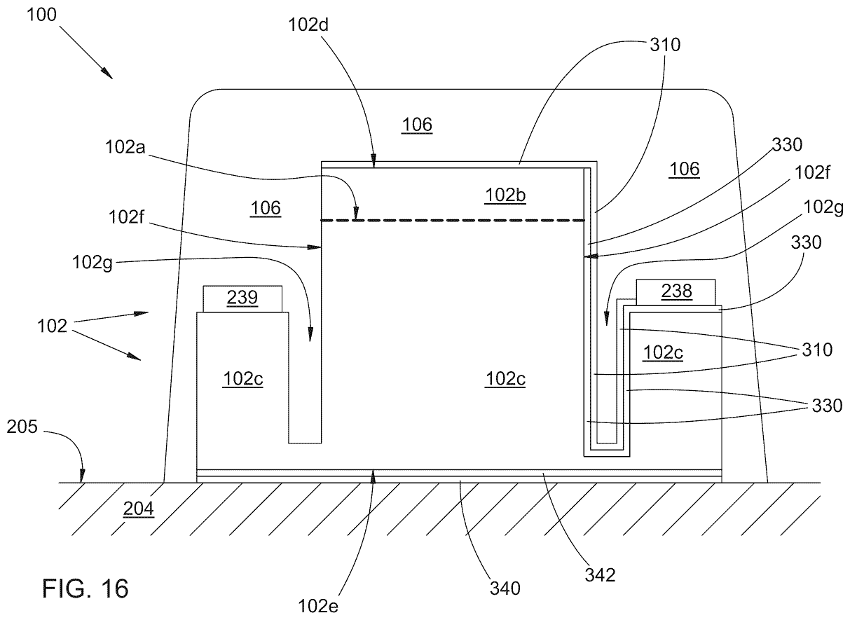

In some examples (e.g., as in FIGS. 12-16), the LED 102 includes lateral portions of the doped layer 102c that extend laterally from the LED sidewalls 102f along the substrate surface 204. In such embodiments the contact pads 238/239 are positioned on the lateral portions of the second doped layer 102c. The contact pad 239 is in direct electrical contact with the doped layer 102c, providing in the electrical connection between them. The electrically insulating layer 330 extends onto the lateral portion of the doped layer 102c and separates it from the contact pad 238. In some of those examples (e.g., as in FIGS. 15 and 16), a trench 102g extends partly through the doped layer 102c between its lateral portions and the LED sidewalls 102f. In such examples the electrical contact 310 extends into and across the trench 102g to reach the contact pad 238, and the insulating layer 330 extends into and across the trench 102g to separate the electrical contact 310 from the doped layer 102c. The trench 102g can reduce the amount of the first output light that propagates into the lateral portions of the doped layer 102c instead of toward the LED surface 102d and the wavelength converter 106.

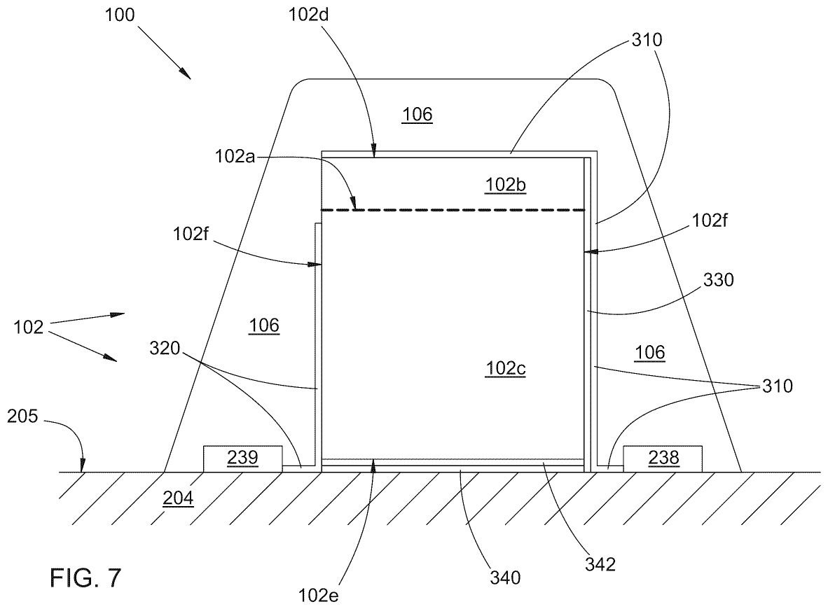

In some examples (e.g., as in FIGS. 4-6, 12, and 15), the wavelength converter 106 covers only the LED surface 102d. In such examples the sidewalls 102f can be made reflective (further described below) over the first output wavelength range, to redirect first output light incident on the LED sidewalls 102f back into the LED 102 to exit (eventually) through the LED surface 102d and enter the wavelength converter 106. In some other examples (e.g., as in FIGS. 7-11, 13, 14, and 16), the wavelength converter 106 covers the LED surface 102d and at least portions of the LED sidewalls 102f. In such examples the sidewalls 102f can be made transmissive (further described below) over the first output wavelength range, to enable first output light incident on the LED sidewalls 102f to exit through the LED sidewalls 102f and enter the wavelength converter 106. In some examples the sidewalls can be made reflective (as described above) but the wavelength converter 106 might extend onto the sidewalls 102f anyway, simply for convenience or ease of manufacturing.

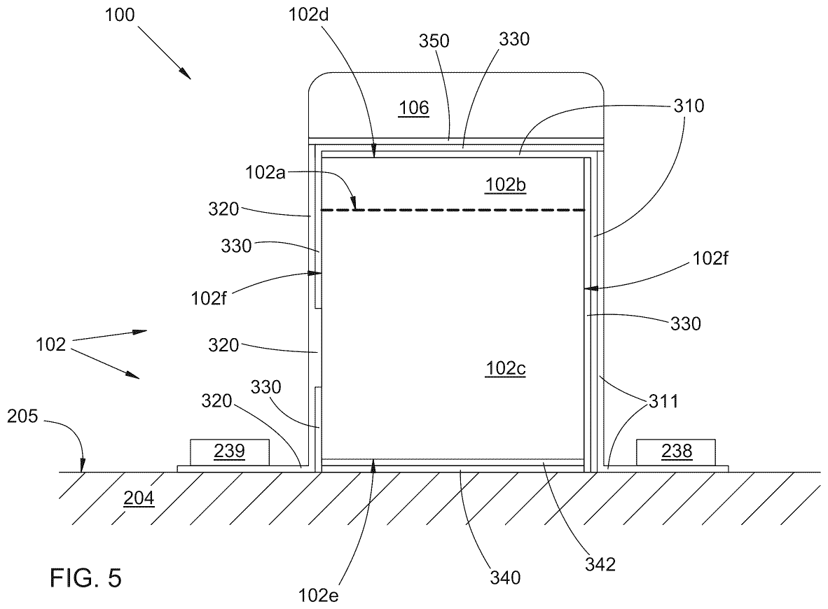

In some examples, including all those shown and described herein, the portion of the electrical contact 310 on the LED surface 102d is transparent over the first output wavelength range, to permit first output light to exit the LED 102 through the LED surface 102d. In some such examples the electrical contact 310 can include a layer of a transparent conductive oxide (TCO; e.g., indium tin oxide or indium zinc oxide or other suitable TCO) on and in direct electrical contact with doped layer 102b at the LED surface 102d. In other such examples, in which the doped layer 102b is a p-doped layer, the electrical contact 310 can include (i) a semiconductor tunnel junction layer on the LED surface 102d in direct contact with the doped layer 102b and (ii) an n-doped layer on the tunnel junction layer. The n-doped layer serves to spread drive current laterally across the LED surface 102d, and the tunnel junction layer enables that current to enter the doped layer 102b. In some examples with a transparent electrical contact 310 on the LED surface 102d, an optical coating 350 can be positioned between the electrical contact 310 and the wavelength converter 106 (e.g., as shown in FIGS. 5, 8, and 11; can be included in any other arrangements shown). The optical coating 350 can be arranged to be transmissive over the first output wavelength range (to enable first output light exiting the LED surface 102d to enter the wavelength converter 106) and to be reflective over the second output wavelength range (to redirect second output light propagating toward the LED surface 102d away from the LED 102). The optical coating 350 can be of any suitable type or arrangement, e.g., a notch filter or a short-pass filter.

In some other examples (not shown), first output light is not intended to exit the LED 102 through the LED surface 102d, but only through the LED sidewalls 102f. In such examples, the electrical contact 310 can be made reflective on the LED surface 102d (e.g., by employing a reflective metal layer such as aluminum or silver in direct contact with the doped layer 102b, or by employing a dielectric reflector layer on a transparent electrical contact 310 on the LED surface 102d). In such examples the wavelength converter 106 would be present on the sidewalls 106, and could optionally be absent from the LED surface 102d.

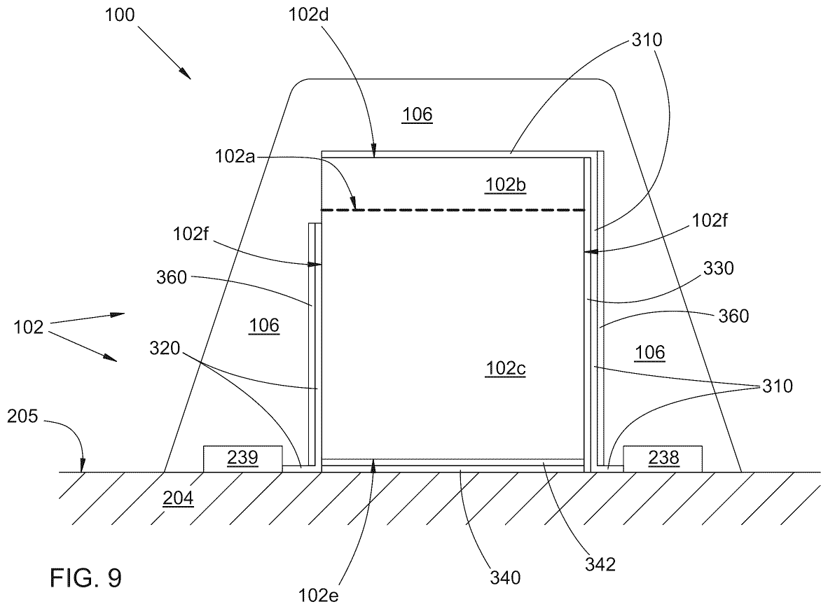

In some examples the LED sidewalls 102f can be transparent over the first output wavelength range, enabling some of the first output light to exit the LED 102 through the LED sidewalls 102f. In such examples the wavelength converter 106 extends onto the sidewalls 106 to absorb at least a portion of the first output light exiting through the LED sidewalls 102f (e.g., as in FIGS. 7-11, 13, 14, and 16). In such examples the electrical contact 310, and the electrical contact 320 (if present), on the LED sidewalls 102f are transparent, typically including a TCO layer. In some such examples, an optical coating 360 can be employed that is transmissive over the first output wavelength range and reflective over the second output wavelength range (e.g., as shown in FIGS. 9 and 11; can be included in any other arrangements shown having the wavelength converter 106 extending onto the LED sidewalls 102f). In such examples the optical coating 360 would be arranged and function as described above for the optical coating 350. An electrically insulating optical coating 360 (e.g., a dielectric multilayer coating) could be positioned between the electrical contact 310 and the LED sidewalls 102f, doubling as the insulating layer 330, or can be positioned with the electrical contact 310 and the insulating layer 330 between the LED sidewalls 102f and the optical coating 360 (e.g., as in FIGS. 9 and 11). In examples that include the electrical contact 320, the electrical contacts 310 and 320 and the insulating layer 330 would all be between the optical coating 360 and respective areas of the LED sidewalls 102f (e.g., as in FIGS. 9 and 11).

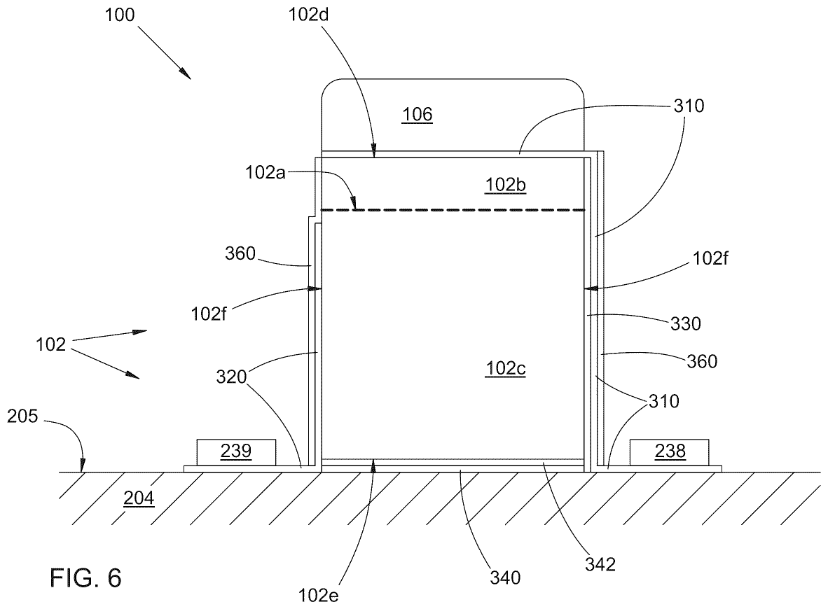

In some examples the LED sidewalls 102f can be reflective over the first output wavelength range, so that first output light incident on the LED sidewalls 102f would be reflected back into the LED 102 to exit (eventually) through the LED surface 102d and enter the wavelength converter 106. In some such examples the electrical contact 310, and the electrical contact 320 (if present) on the LED sidewalls 102a can be reflective (e.g., metallic layers, in direct contact with the corresponding doped layer, or with a TCO layer between the metallic layer and the corresponding doped layer). In other such examples transparent electrical contacts 310 (and 320, if present) can be employed, and an optical coating 360 can be positioned on the contacts and arranged to reflect the first output light (e.g., as shown in FIG. 6; can be similarly arranged in other examples in which the first output light is intended to exit only through the LED surface 102d). In some of those examples the optical coating can be metallic; in some other of those examples the optical coating can be electrically insulating. As described above (when the optical coating 360 is transmissive over the first output wavelength range, reflective over the second output wavelength range, and electrically insulating), the electrically insulating optical coating 360 can double as the insulating layer 330 in some examples, or the electrical contacts 310 and 320 and the insulating layer 330 can be between the optical coating 360 and the corresponding portions of the LED sidewalls 102f.

The specific examples of FIGS. 4-15 will now be described in more detail. In FIG. 4 the contact pads 238/239 are on the substrate surface 205, the wavelength converter 106 is on only the LED surface 102d, and reflective layer 340 and surface 342 are between the LED surface 102e and the substrate surface 205. The portion of the electrical contact 310 on the LED surface 102d is transparent (e.g., a TCO layer, or a tunnel junction and additional doped layer) and extends along a portion of the LED sidewalls 102f; the electrical contact 310 can further include a reflective layer 311 (e.g., a metallic layer) to reflect the first output light back into the LED 102, and in some examples (e.g., FIGS. 4, 5, 12, or 15) to provide electrical continuity with the contact pad 238. The electrical contact 320 on the LED sidewalls 102f typically would also be reflective (e.g., a metallic contact) to reflect the first output light back into the LED 102. The insulating layer 330 is arranged to separate the electrical contact 320 from the doped layer 102b and the active layer(s) 102a, but to permit electrical contact with the doped layer 102c. FIG. 5 is similar to FIG. 4 with the addition of the optical coating 350 between the wavelength converter 106 and the LED surface 102d, which would typically be arranged to transmit the first output light while reflective the second output light (as described above). FIG. 6 is similar to FIG. 4 with the additional of the optical coating 360 on the LED sidewalls 102f. The optical coating 360 typically would reflect the first output light back into the LED 102, and the electrical contact 310 and 320 on the LED sidewalls would typically be transparent (e.g., TCO layers); the metallic layer 311 would not be needed. Note that both optical coatings 350/360, arranged as in FIGS. 5 and 6, can be used together in a given device if needed or desirable.

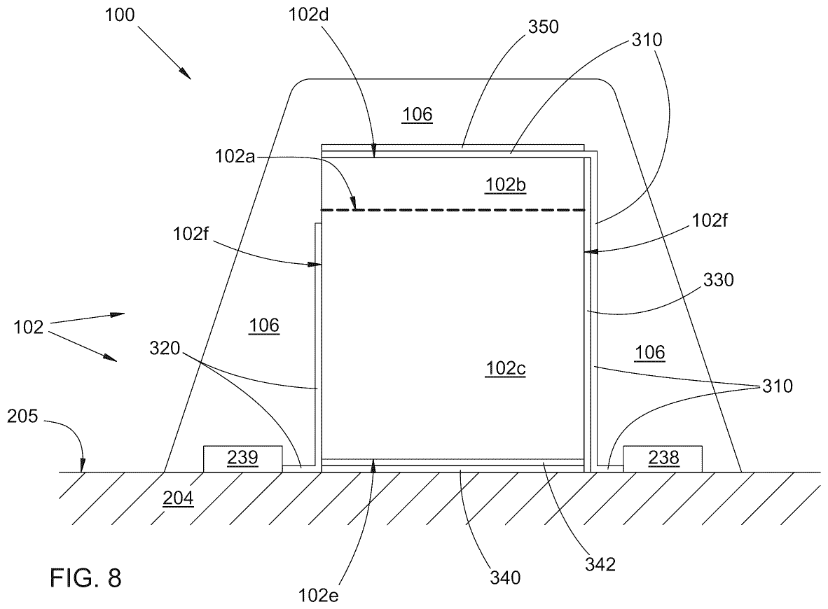

FIG. 7 is similar to FIG. 4 except that the wavelength converter extends onto the LED sidewalls 102f. In this example the electrical contacts 310/320 typically would be transparent to allow first output light to exit through the LED sidewalls 102f and enter the wavelength converter 106. FIG. 8 includes the optical coating 350 on the LED surface 102d; the optical coating 350 can be arranged in this example as describe above for FIG. 5. FIG. 9 includes the optical coating 360 on the LED sidewalls 102f, in this example arranged to transmit the first output light and reflect the second output light (similar to the optical coating 350, and in contrast to the optical coating 360 of FIG. 6). Note that both optical coatings 350/360, arranged as in FIGS. 8 and 9, can be used together in a given device if needed or desirable.

FIG. 10 is similar to FIG. 7 except that the LED sidewalls 102f form an acute angle with respect to the substrate surface 205. Those angled LED sidewalls 102f can increase the amount of the first output light that exits through the LED sidewalls 102f and enters the wavelength converter 106. FIG. 11 is similar to FIG. 10 with the additional of the optical coating 350 on the LED surface 102d and the optical coating 360 on the LED sidewalls 102f. Both of those optical coatings 350/360 typically would be arranged to transmit the first output light and reflect the second output light. Note that either of the optical coatings 350 or 360 could be used without the other in this general arrangement, if needed or desirable.

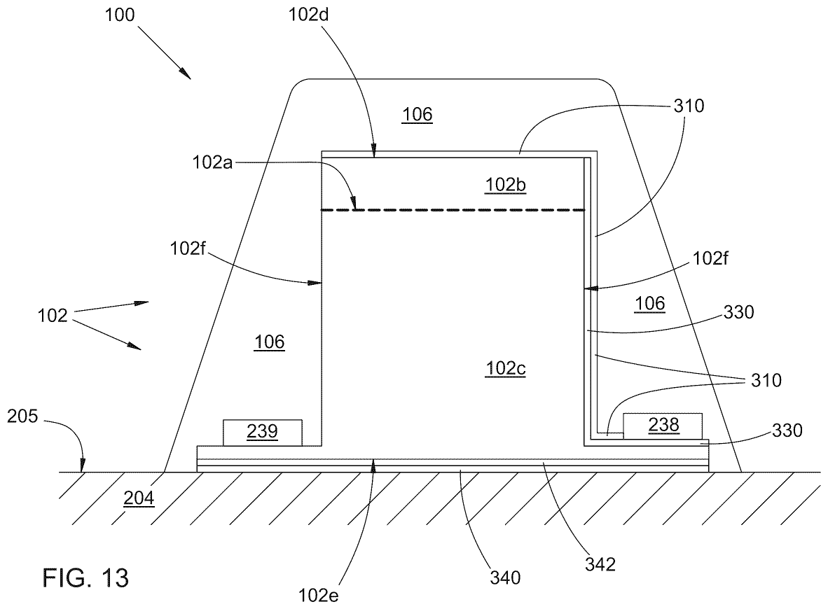

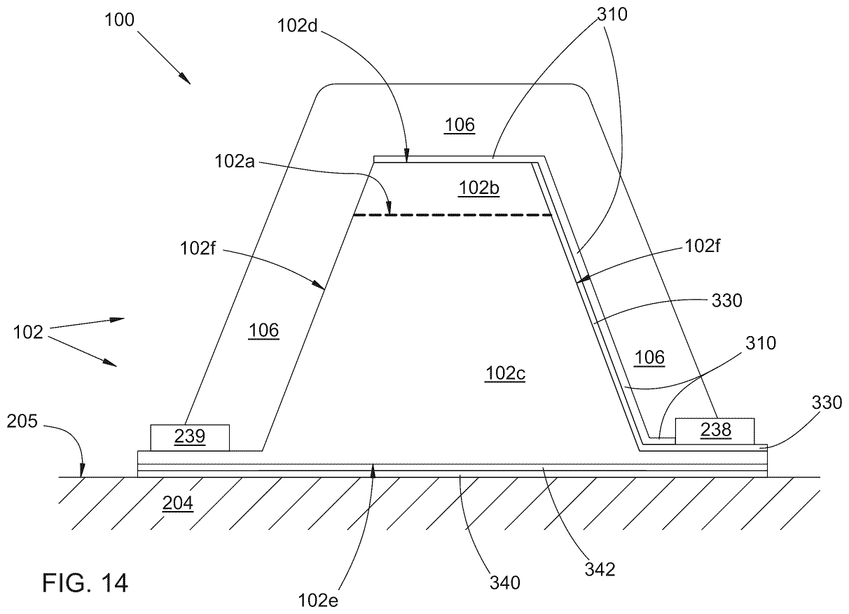

FIG. 12 is similar to FIG. 4 except that the contact pads 238/239 are on laterally extending portions of the LED doped layer 102c, and the electrical contact 320 is replaced by metallic reflector 322; FIG. 13 is analogously similar to FIG. 7 (but without the reflector 322); FIG. 14 is analogously similar to FIG. 10 (but without the reflector 322). The contact pad 239 is in direct electrical contact with the doped layer 102c; the contact pad 238 is separated from the doped layer 102c by a portion of the insulating layer 330. The arrangements of FIG. 12 or 13 or 14 can be modified in a manner analogous to modification of the arrangements of FIG. 4 or 7 or 10 to form arrangements analogous to those of FIGS. 5 and 6, FIGS. 8 and 9, or FIG. 11, respectively.

FIG. 15 is similar to FIG. 12 with the addition of the trenches 102g separating laterally extending portion of the doped layer 102c from the LED sidewalls 102f; FIG. 16 is analogously similar to FIG. 13 (but without the reflector 322). The arrangements of FIG. 15 or 16 can be modified in a manner analogous to modification of the arrangements of FIG. 4 or 7 to form arrangements analogous to those of FIGS. 5 and 6 or FIGS. 8 and 9, respectively.

In addition to the preceding, the following example embodiments fall within the scope of the present disclosure or appended claims. Any given Example below that refers to multiple preceding Examples shall be understood to refer to only those preceding Examples with which the given Example is not inconsistent, and to exclude implicitly those preceding Examples with which the given Example is inconsistent.
Example 1. A wavelength-converted light-emitting device comprising: (a) a semiconductor light-emitting diode (LED) having opposite first and second LED surfaces and LED sidewalls extending from the first LED surface toward the second LED surface, the LED being positioned on a substrate surface with the second LED surface on the substrate surface, the LED including (i) one or more light-emitting active regions arranged so as to emit first output light in a first output wavelength range, (ii) a first doped semiconductor layer between the first LED surface and the one or more active regions, and (iii) a second doped semiconductor layer between second LED surface and the one or more active regions; (b) a wavelength converter positioned on at least the first LED surface, the wavelength converter absorbing at least a portion of the first output light that enters the wavelength converter and emitting second output light in a second output wavelength range that is longer than the first output wavelength range; (c) first and second electrical contact pads on the LED or on the substrate surface adjacent the LED, the first and second electrical contact pads being electrically isolated from each other; (d) a first electrical contact, on at least a portion of the first LED surface, that is in direct electrical contact with the first doped layer of the LED, the first electrical contact extending over a portion of the LED sidewalls and being arranged to form a first electrical connection, between the first contact pad and the first doped layer; (e) a second electrical connection, between the second contact pad and the second doped layer; and (f) a first electrically insulating layer, on a portion of the LED sidewalls, that separates the first electrical contact from the one or more active regions and from the second doped layer.
Example 2. The light-emitting device of Example 1 wherein (i) the LED sidewalls connect the first and second LED surfaces, (ii) the first and second contact pads are positioned the substrate surface adjacent the LED, and (iii) the light-emitting device further comprises a second electrical contact that is in direct electrical contact with the second doped layer of the LED, arranged to connect the second contact pad to the second doped layer, and electrically isolated from the one or more active regions and the first doped layer of the LED.
Example 3. The light-emitting device of Example 2 wherein the LED sidewalls are perpendicular to the substrate surface.
Example 4. The light-emitting device of Example 2 wherein the LED sidewalls form an acute angle with the substrate surface so that a vertical cross-section of the LED is trapezoidal with the second LED surface being wider than the first LED surface, the acute angle being less than 70°.
Example 5. The light-emitting device of Example 1 wherein (i) the LED includes lateral portions of the second doped layer that extend laterally from the LED sidewalls along the substrate surface, (ii) the first and second contact pads are positioned on the lateral portions of the second doped layer, (iii) a portion of the first electrically insulating layer extends onto the lateral portion of the second doped layer and separates the first contact pad from the second doped layer, and (iv) the second contact pad is in direct electrical contact with the second doped layer.
Example 6. The light-emitting device of Example 5 wherein (i) a trench extends partly through the second doped layer between the lateral portions thereof and the LED sidewalls, (ii) the first electrical contact extends into and across the trench to reach the first contact pad, and (iii) the first insulating layer extends into an across the trench to separate the first electrical contact from the second doped layer.
Example 7. The light-emitting device of any one of Examples 1 through 6 wherein the wavelength converter covers only the first LED surface.
Example 8. The light-emitting device of any one of Examples 1 through 6 wherein the wavelength converter covers the first LED surface and at least portions of the LED sidewalls.
Example 9. The light-emitting device of Example 8 wherein, on the LED sidewalls, the first electrical contact, or a second electrical contact connecting the second contact pad to the second doped layer, includes one or more transparent conductive oxides (TCOs).
Example 10. The light-emitting device of any one of Examples 1 through 9 wherein the wavelength converter includes a multitude of quantum dots that absorb light in the first output wavelength range and emit light in the second output wavelength range.
Example 11. The light-emitting device of any one of Examples 1 through 10 further comprising a reflective layer between the substrate surface and the second doped layer that is reflective over the first output wavelength range.
Example 12. The light-emitting device of Example 11 further comprising a roughened, patterned, scattering, or diffractive surface between the reflective layer and the second doped layer.
Example 13. The light-emitting device of any one of Examples 1 through 12 further comprising a layer or an optical coating on the LED sidewalls that is reflective over the first output wavelength range.
Example 14. The light-emitting device of Example 13 wherein the optical coating comprises a multilayer dielectric coating or a metallic coating.
Example 15. The light-emitting device of any one of Examples 1 through 14 further comprising an optical coating on the first LED surface between the LED and the wavelength converter that is transparent over the first output wavelength range and reflective over the second output wavelength range.
Example 16. The light-emitting device of Example 15 wherein the optical coating extends onto the LED sidewalls.
Example 17. The light-emitting device of any one of Examples 1 through 16 wherein, on the first LED surface, the first electrical contact includes either (i) a layer of one or more transparent conductive oxides (TCOs) or (ii) a third doped semiconductor layer and a semiconductor tunnel-junction layer between the first and third doped layers.
Example 18. The light-emitting device of any one of Examples 1 through 17 wherein either: (i) the first output wavelength range includes one or more UV wavelengths, the second output wavelength range includes one or more visible wavelengths, and the wavelength converter is arranged to absorb substantially all of the entering first output light, so that overall output of the light-emitting device includes light in only the second wavelength range; or (ii) both the first and second output wavelength ranges include visible wavelengths, and the wavelength converter is arranged to absorb only a portion of the entering first output light, so that overall output of the light-emitting device includes light in both the first and second wavelength ranges.
Example 19. The light-emitting device of any one of Examples 1 through 18 wherein (i) the LED includes one or more doped or undoped III-V, II-VI, or Group IV semiconductor materials, or mixtures, alloys, or compounds thereof, (ii) the first doped layer is a p-doped layer and the second doped layer is an n-doped layer, or (iii) the one or more active regions include one or more quantum wells, one or more multi-quantum wells, or quantum dots.
Example 20. The light-emitting device of any one of Examples 1 through 19 further comprising a light-emitting array that includes the light-emitting device and multiple additional similarly arranged light-emitting devices.
Example 21. The light emitting array of Example 20 wherein: (i) spacing of the light-emitting devices of the array is less than 1 millimeter, less than 500 microns, less than 200 microns, less than 100 microns, less than 50 microns, less than 20 microns, less than 10 microns, or less than 5 microns; or (ii) separation between light-emitting devices of the array is less than 200 microns, less than 100 microns, less than 50 microns, less than 20 microns, less than 10 microns, or less than 5 microns.

This disclosure is illustrative and not limiting. Further modifications will be apparent to one skilled in the art in light of this disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed example embodiment. Therefore, the present disclosure shall be construed as implicitly disclosing any embodiment having any suitable subset of one or more features—which features are shown, described, or claimed in the present application—including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open-ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth, or if a differing interpretation is implicit or inherent (e.g., some small integer quantities). For null quantities described by phrases such as “equal to zero,” “absent,” “eliminated,” “negligible,” “prevented,” and so forth (with or without terms such as “about,” “substantially,” and so forth), each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled. Terms such as “parallel,” “perpendicular,” “orthogonal,” “flush,” “aligned,” and so forth shall be similarly interpreted (with or without terms such as “about,” “substantially,” and so forth).

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC §112(f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC §112(f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A wavelength-converted light-emitting device comprising:
(a) a semiconductor light-emitting diode (LED) having opposite first and second LED surfaces and LED sidewalls extending from the first LED surface toward the second LED surface, the LED being positioned on a substrate surface with the second LED surface on the substrate surface, the LED including (i) one or more light-emitting active regions arranged so as to emit first output light in a first output wavelength range, (ii) a first doped semiconductor layer between the first LED surface and the one or more active regions, and (iii) a second doped semiconductor layer between second LED surface and the one or more active regions;
(b) a wavelength converter positioned on at least the first LED surface, the wavelength converter absorbing at least a portion of the first output light that enters the wavelength converter and emitting second output light in a second output wavelength range that is longer than the first output wavelength range;
(c) first and second electrical contact pads on the LED or on the substrate surface adjacent the LED, the first and second electrical contact pads being electrically isolated from each other;
(d) a first electrical contact, on at least a portion of the first LED surface, that is in direct electrical contact with the first doped layer of the LED, the first electrical contact extending over a portion of the LED sidewalls and being arranged to form a first electrical connection, between the first contact pad and the first doped layer;
(e) a second electrical connection, between the second contact pad and the second doped layer; and
(f) a first electrically insulating layer, on a portion of the LED sidewalls, that separates the first electrical contact from the one or more active regions and from the second doped layer.

2. The light-emitting device of claim 1 wherein (i) the LED sidewalls connect the first and second LED surfaces, (ii) the first and second contact pads are positioned the substrate surface adjacent the LED, and (iii) the light-emitting device further comprises a second electrical contact on a portion of the LED sidewalls that is in direct electrical contact with the second doped layer of the LED, arranged to connect the second contact pad to the second doped layer, and electrically isolated from the one or more active regions and the first doped layer of the LED.

3. The light-emitting device of claim 2 wherein the LED sidewalls are perpendicular to the substrate surface.

4. The light-emitting device of claim 2 wherein the LED sidewalls form an acute angle with the substrate surface so that a vertical cross-section of the LED is trapezoidal with the second LED surface being wider than the first LED surface, the acute angle being less than 70°.

5. The light-emitting device of claim 1 wherein (i) the LED includes lateral portions of the second doped layer that extend laterally from the LED sidewalls along the substrate surface, (ii) the first and second contact pads are positioned on the lateral portions of the second doped layer, (iii) a portion of the first electrically insulating layer extends onto the lateral portion of the second doped layer and separates the first contact pad from the second doped layer, and (iv) the second contact pad is in direct electrical contact with the second doped layer.

6. The light-emitting device of claim 5 wherein (i) a trench extends partly through the second doped layer between the lateral portions thereof and the LED sidewalls, (ii) the first electrical contact extends into and across the trench to reach the first contact pad, and (iii) the first insulating layer extends into an across the trench to separate the first electrical contact from the second doped layer.

7. The light-emitting device of claim 1 wherein the wavelength converter covers only the first LED surface.

8. The light-emitting device of claim 1 wherein the wavelength converter covers the first LED surface and at least portions of the LED sidewalls.

9. The light-emitting device of claim 8 wherein, on the LED sidewalls, the first electrical contact, or a second electrical contact connecting the second contact pad to the second doped layer, includes one or more transparent conductive oxides (TCOs).

10. The light-emitting device of claim 1 wherein the wavelength converter includes a multitude of quantum dots that absorb light in the first output wavelength range and emit light in the second output wavelength range.

11. The light-emitting device of claim 1 further comprising a reflective layer between the substrate surface and the second doped layer that is reflective over the first output wavelength range.

12. The light-emitting device of claim 11 further comprising a roughened, patterned, scattering, or diffractive surface between the reflective layer and the second doped layer.

13. The light-emitting device of claim 1 further comprising a layer or an optical coating on the LED sidewalls that is reflective over the first output wavelength range.

14. The light-emitting device of claim 13 wherein the optical coating comprises a multilayer dielectric coating or a metallic coating.

15. The light-emitting device of claim 1 further comprising an optical coating on the first LED surface between the LED and the wavelength converter that is transparent over the first output wavelength range and reflective over the second output wavelength range.

16. The light-emitting device of claim 15 wherein the optical coating extends onto the LED sidewalls.

17. The light-emitting device of claim 1 wherein, on the first LED surface, the first electrical contact includes either (i) a layer of one or more transparent conductive oxides (TCOs) or (ii) a third doped semiconductor layer and a semiconductor tunnel-junction layer between the first and third doped layers.

18. The light-emitting device of claim 1 wherein either:
(i) the first output wavelength range includes one or more UV wavelengths, the second output wavelength range includes one or more visible wavelengths, and the wavelength converter is arranged to absorb substantially all of the entering first output light, so that overall output of the light-emitting device includes light in only the second wavelength range; or
(ii) both the first and second output wavelength ranges include visible wavelengths, and the wavelength converter is arranged to absorb only a portion of the entering first output light, so that overall output of the light-emitting device includes light in both the first and second wavelength ranges.

19. The light-emitting device of claim 1 wherein (i) the LED includes one or more doped or undoped III-V, II-VI, or Group IV semiconductor materials, or mixtures, alloys, or compounds thereof, (ii) the first doped layer is a p-doped layer and the second doped layer is an n-doped layer, or (iii) the one or more active regions include one or more quantum wells, one or more multi-quantum wells, or quantum dots.

20. The light-emitting device of claim 1 further comprising a light-emitting array that includes the light-emitting device and multiple additional similarly arranged light-emitting devices.
